(19) United States
(12) Patent Application Publication
(10) Pub. No.: US 2024/0326406 A1
(43) Pub. Date: Oct. 3, 2024

(54) SUBSTRATE PROCESSING APPARATUS AND METHOD THEREOF

(71) Applicant: SEMES CO., LTD., Chungcheongnam-do (KR)

(72) Inventor: Seong Soo JEONG, Chungcheongnam-do (KR)

(21) Appl. No.: 18/420,513

(22) Filed: Jan. 23, 2024

(30) Foreign Application Priority Data
Mar. 31, 2023 (KR) 10-2023-0043094

(51) Int. Cl. B41J 2/045; B41J 3/407; H01L 21/67

(52) U.S. Cl. CPC B41J 2/04505; B41J 2/04581; B41J 3/407; H01L 21/6715

(57) ABSTRACT

Provided is a substrate processing apparatus and method that can synchronize the position of the substrate and the impact position of the nozzle. The substrate processing apparatus comprises a process processing unit including a stage supporting a substrate and for moving the substrate on the stage; an inkjet head unit for discharging a substrate processing liquid onto the substrate; a gantry unit for moving the inkjet head unit; and a jetting driver for controlling discharge of the substrate processing liquid, wherein a first signal controlling a position of the substrate and a second signal controlling a position of the inkjet head unit are synchronized.

This application claims the benefit of Korean Patent Application No. 10-2023-0043094, filed on Mar. 31, 2023, in the Korean Intellectual Property Office, the disclosure of which is incorporated herein by reference in its entirety.

### BACKGROUND

### 1. Field

The present disclosure relates to a substrate processing apparatus and method. More specifically, it relates to a substrate processing apparatus and method for processing a substrate using an inkjet printing method.

### 2. Description of the Related Art

When manufacturing display devices such as LCD panels, LED panels, organic EL devices, etc., a printing process can be performed on a transparent substrate using inkjet printing equipment. Inkjet printing equipment can perform a patterning process (for example, RGB patterning) at a desired position on a transparent substrate by discharging fine-sized ink droplets using an inkjet head.

In order to discharge liquid droplets at a desired position on the substrate, it is necessary to synchronize the position of the substrate and the position of each nozzle of the inkjet head. However, in conventional inkjet printing equipment, the device that controls the position of the substrate and the device that controls the impact position of the nozzle are different, so there is difficulty in synchronization.

### SUMMARY

The technical problem to be solved by the present disclosure is to provide a substrate processing apparatus and method that can synchronize the position of the substrate and the impact position of the nozzle.

The technical problems of the present disclosure are not limited to the technical problems mentioned above, and other technical problems not mentioned will be clearly understood by those skilled in the art from the description below.

One aspect of the substrate processing apparats of the present disclosure for achieving the above technical problem comprises a process processing unit including a stage supporting a substrate and for moving the substrate on the stage; an inkjet head unit for discharging a substrate processing liquid onto the substrate; a gantry unit for moving the inkjet head unit; and a jetting driver for controlling discharge of the substrate processing liquid, wherein a first signal controlling a position of the substrate and a second signal controlling a position of the inkjet head unit are synchronized.

One aspect of the substrate processing method of the present disclosure for achieving the above technical problem comprises recognizing a position of a substrate; recognizing a position of an inkjet head unit for discharging a substrate processing liquid on the substrate; synchronizing a first signal controlling a position of the substrate and a second signal controlling a position of the inkjet head unit; and controlling discharge of the substrate processing liquid based on synchronization of the first signal and the second signal.

Another aspect of the substrate processing apparats of the present disclosure for achieving the above technical problem comprises a process processing unit including a stage supporting a substrate and for moving the substrate on the stage; an inkjet head unit for discharging a substrate processing liquid onto the substrate; a gantry unit for moving the inkjet head unit; a jetting driver for controlling discharge of the substrate processing liquid; a first control unit for recognizing and controlling a position of the substrate; and a second control unit for controlling the jetting driver, wherein a first signal controlling a position of the substrate and a second signal controlling a position of the inkjet head unit are synchronized, wherein the first control unit or the second control unit recognizes and controls a position of the inkjet head unit, wherein a transmission signal between the first control unit and the second control unit is a digital signal, wherein a transmission signal between the second control unit and the jetting driver is an analog signal.

Details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view schematically showing the internal structure of a substrate processing apparatus that processes a substrate using an inkjet printing method;

FIG. 2 is a diagram schematically showing the internal structure of an inkjet head unit constituting a substrate processing apparatus;

FIG. 3 is a block diagram schematically showing the internal configuration of a substrate processing system including a substrate processing apparatus;

FIG. 4 is a first example diagram for explaining a first control unit, a second control unit, and a jetting driver that constitute a substrate processing apparatus;

FIG. 5 is a first example diagram for explaining the function of the first control unit constituting the substrate processing apparatus;

FIG. 6 is a second example diagram for explaining the function of the first control unit constituting the substrate processing apparatus;

FIG. 7 is a first example diagram for explaining the function of the second control unit constituting the substrate processing apparatus;

FIG. 8 is a second example diagram for explaining the function of the second control unit constituting the substrate processing apparatus;

FIG. 9 is a third example diagram for explaining the function of the second control unit constituting the substrate processing apparatus;

FIG. 10 is a fourth example diagram for explaining the function of the second control unit constituting the substrate processing apparatus;

FIG. 11 is a second example diagram for explaining a first control unit, a second control unit, and a jetting driver that constitute a substrate processing apparatus;

FIG. 12 is an example diagram for explaining signals input and output from the first control unit and the second control unit constituting the substrate processing apparatus; and

FIG. 13 is a flowchart sequentially explaining the substrate processing method of the substrate processing apparatus.

### DETAILED DESCRIPTION

Hereinafter, embodiments of the present disclosure will be described in detail with reference to the attached drawings. The same reference numerals are used for the same components in the drawings, and duplicate descriptions thereof are omitted.

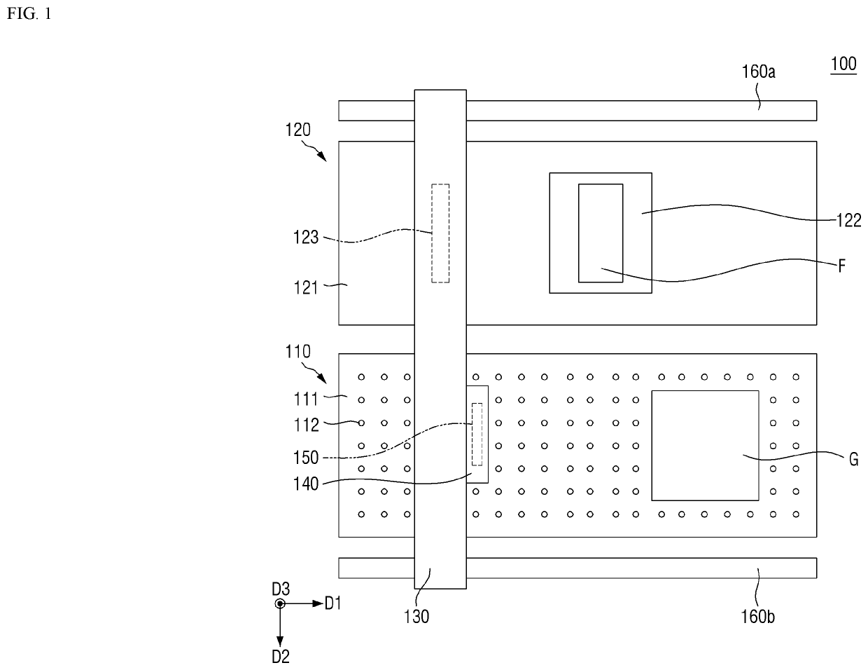

FIG. 1 is a plan view schematically showing the internal structure of a substrate processing apparatus that processes a substrate using an inkjet printing method. According to FIG. 1, the substrate processing apparatus 100 may comprise a process processing unit 110, a maintenance unit 120, a gantry unit 130, an inkjet head unit 140, and a substrate processing liquid providing unit 150.

The substrate processing apparatus 100 can process a substrate G used to manufacture a display device. The substrate processing apparatus 100 may be provided as an inkjet printing equipment that performs a printing process on the substrate G by discharging (jetting) a substrate processing liquid on the substrate G using the inkjet head unit 140. The substrate G may be, for example, transparent glass.

The substrate processing liquid refers to a chemical liquid used to print the substrate G. The substrate processing apparatus 100 can use ink as this substrate processing liquid. For example, the substrate processing liquid may be quantum dot (QD) ink containing ultrafine semiconductor particles. The substrate processing apparatus 100 can perform pixel printing on the substrate G using ink of various colors and can form a color filter (CF) on the substrate G. Additionally, the substrate processing apparatus 100 may be provided as a circulatory system to prevent nozzles in the inkjet head unit 140 from being clogged by ink.

The process processing unit 110 serves to support the substrate G while processing the substrate G using a substrate processing liquid. The process processing unit 110 may support the substrate G using a contact method, and may also support the substrate G using a non-contact method. When supporting the substrate G using a contact method, the process processing unit 110, for example, may support the substrate G by adsorbing the substrate G to a chuck provided with a plate-shaped seating surface on the top. When supporting the substrate G using a non-contact method, the process processing unit 110 may support the substrate G by levitating the substrate G in the air using, for example, air.

The process processing unit 110 may support the substrate G and simultaneously move the substrate G from one direction to the other direction. For example, the process processing unit 110 may include a first stage 111 and an air hole 112.

The first stage (1st stage) 111 is a base, and may be provided so that the substrate G is seated on it. The air hole 112 may be formed penetrating through the upper and lower portions of the first stage 111, and may be formed in plural numbers in the printing zone provided on the first stage 111.

The air hole 112 may spray air toward the upper direction of the first stage 111 (third direction D3). The air hole 112 can levitate the substrate G seated on the first stage 111 into the air.

Although not shown in FIG. 1, the process processing unit 110 may further include a gripper and a guide rail. When the substrate G moves along the longitudinal direction (first direction D1) of the first stage 111, the gripper grips the substrate G and prevents the substrate G from being separated from the first stage 111. When the substrate G moves, the gripper may move in the same direction as the substrate G along the guide rail while gipping the substrate G. The gripper and the guide rail may be provided outside the first stage 111.

The maintenance unit 120 serves to maintain the substrate G. For example, the maintenance unit 120 can play a role to measure whether the substrate processing liquid is discharged on the substrate G in the form of a droplet, the droplet's landing point (discharge position), volume, range (area), speed, etc. and provide such measurement results to the control unit. The control unit will be described later.

The maintenance unit 120 may be configured to include a second stage 121, a measurement module 122, and a vision module 123 for inspection of droplets. Here, the second stage 121 is a base like the first stage 111, and may be arranged in parallel with the first stage 111. The second stage 121 may include a maintenance zone provided on its upper portion, and may be provided in the same size as the first stage 111, but it is also possible to be provided in a different size from the first stage 111.

The measurement module 122 and the vision module 123 serve to directly inspect the droplets. As will be described later, in this embodiment, the droplet inspection unit may be configured to include the vision module 123. Alternatively, the droplet inspection unit may be configured to include the measurement module 122 and the vision module 123.

The measurement module 122 may include a substrate F onto which a substrate processing liquid is discharged, and the substrate F may be used for droplet inspection and may have a film form. The measurement module 122 may be provided as, for example, a jetting on film (JOF) module. The measurement module 122 may include a calibration board including an alignment mark and a ruler to measure the droplet's landing position.

The vision module 123 serves to obtain an image related to the liquid droplet when the substrate processing liquid is discharged on the substrate F for inspection. The vision module 123 may include a camera for this purpose and, for example, may be provided as a nozzle jetting inspection (NJI) module.

When the substrate processing liquid is discharged on the substrate F for inspection, the vision module 123 can obtain images related to the liquid droplets in real time. The vision module 123 can obtain an image by photographing the substrate F for inspection in the longitudinal direction (first direction D1). In this case, the vision module 123 may be configured to include a line scan camera. Alternatively, the vision module 123 may obtain an image by photographing the substrate F for inspection in each area of a predetermined size. In this case, the vision module 123 may be configured to include an area scan camera.

The vision module 123 may serve to obtain an image of the substrate F for inspection on the maintenance unit 120, but is not limited thereto, and may also serve to obtain an image of the substrate F for product production when it is processed on the process processing unit 110. The vision module 123 may be installed on the bottom surface or side surface of the gantry unit 130 for this purpose. However, this embodiment is not limited to this. The vision module 123 may be installed on the front surface or side surface of the inkjet head unit 140, and may also be movable rather than fixed on the gantry unit 130 or the inkjet head unit 140.

Although not shown in FIG. 1, the maintenance unit 120 may include a guide rail that can guide the movement path of the measurement module 122. The guide rail may be provided to guide the measurement module 122 in the longitudinal direction (first direction D1) or the width direction (second direction D2) of the second stage 121, and, for example, it can be provided as an LM guide system (Linear Motion Guide System).

The gantry unit 130 serves to support the inkjet head unit 140. The gantry unit 130 may be disposed on the top of first stage 111 and the second stage 121 so that the inkjet head unit 140 can discharge the substrate processing liquid onto the substrates G and F.

The gantry unit 130 may be disposed on the first stage 111 and the second stage 121 with the width direction (second direction D2) of the first stage 111 and the second stage 121 as the longitudinal direction. The gantry unit 130 may move in the longitudinal direction (first direction D1) of the first stage 111 and the second stage 121 according to the guides of the first guide rail 160a and the second guide rail 160b. The first guide rail 160a and the second guide rail 160b may be provided outside the first stage 111 and the second stage 121, respectively, and may be provided along the longitudinal direction (first direction D1) of the first stage 111 and the second stage 121. The first guide rail 160a and the second guide rail 160b may be provided as, for example, an LM guide system.

Although not shown in FIG. 1, the substrate processing apparatus 100 may further include a gantry movement unit. The gantry movement unit serves to control the gantry unit 130 to slide along the first guide rail 160a and the second guide rail 160b. The gantry movement unit may include a motor and may be installed inside the gantry unit 130, but may also be installed outside the gantry unit 130.

The inkjet head unit 140 serves to discharge the substrate processing liquid in the form of droplets on the substrate G. The inkjet head unit 140 may be installed on the side surface or bottom surface of the gantry unit 130.

At least one inkjet head unit 140 may be installed in the gantry unit 130. When a plurality of inkjet head units 140 are installed in the gantry unit 130, the plurality of inkjet head units 140 may be arranged in a row along the longitudinal direction (second direction D2) of the gantry unit 130. Additionally, the plurality of inkjet head units 140 may operate independently or, conversely, may operate in union.

The inkjet head unit 140 may move along the longitudinal direction (second direction D2) of the gantry unit 130 to be located at a desired point on the substrate G. Additionally, the inkjet head unit 140 can move along the height direction (third direction D3) of the gantry unit 130 and can also rotate clockwise or counterclockwise. On the other hand, the inkjet head unit 140 may be fixed to the gantry unit 130, and in this case, the gantry unit 130 may be provided to be movable on the substrate G.

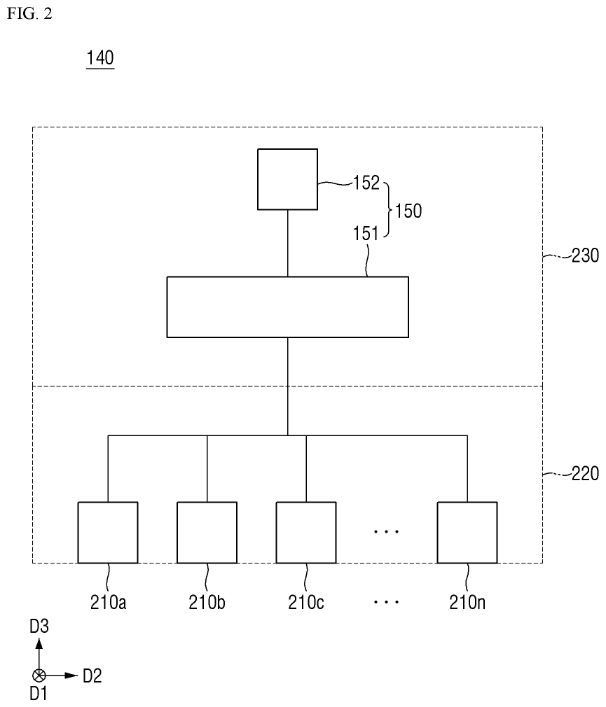

Referring to the example of FIG. 2, the inkjet head unit 140 may include head packs 210a, 210b, 210c, . . . , 210n, a head base 220, and a head frame 230. FIG. 2 is a diagram schematically showing the internal structure of an inkjet head unit constituting a substrate processing apparatus. The following description refers to FIGS. 1 and 2.

The head packs 210a, 210b, 210c, . . . , 210n are a collection of multiple nozzles for pixel printing the substrate G. The head packs 210a, 210b, 210c, . . . , 210n may be formed to have the same size and may discharge a substrate processing liquid of a specific color onto the substrate G. For example, the first head pack 210a may discharge red color ink onto the substrate G. Additionally, the second head pack 210b may discharge green color ink onto the substrate G. Additionally, the third head pack 210c may discharge blue color ink onto the substrate G.

The head packs 210a, 210b, 210c, . . . , 210n may include a plurality of heads. For example, the head packs 210a, 210b, 210c, . . . , 210n include four heads, and each head may include a plurality of nozzles. However, it is not limited to this, and in order to adjust the resolution of the image formed on the substrate G through pixel printing, the number of heads in the head packs 210a, 210b, 210c, . . . , 210n can be varied. Additionally, the plurality of heads in the head packs 210a, 210b, 210c, . . . , 210n may not be arranged in a row, but may be arranged in a plurality of rows.

A plurality of head packs 210a, 210b, 210c, . . . , 210n may be installed in the head base 220. The plurality of head packs 210a, 210b, 210c, . . . , 210n expose a plurality of nozzles to the bottom surface of the head base 220 to enable discharge of the substrate processing liquid, and may be arranged in a plurality of rows within the head base 220 and may be arranged in a zigzag pattern in each row.

The head frame 230 fixes the head base 220 to the gantry unit 130. The substrate processing liquid providing unit 150 may be installed within the head frame 230. The head frame 230 may be disposed on top of the head base 220.

Although not shown in FIG. 1, the substrate processing apparatus 100 may further include an inkjet head movement unit. The inkjet head movement unit may serve to move the inkjet head unit 140 linearly or rotationally.

The substrate processing liquid providing unit 150 may be provided to include a reservoir that provides substrate processing liquid to the inkjet head unit 140. The substrate processing liquid providing unit 150 may include a storage tank 151 and a pressure control module 152.

The storage tank 151 stores the substrate processing liquid, and plays a role in supplying the substrate processing liquid to each head pack 210a, 210b, 210c, . . . , 210n or each nozzle in the head pack 210a, 210b, 210c, . . . , 210n.

The pressure control module 152 serves to regulate the internal pressure of the storage tank 151. The pressure control module 152 can control the meniscus of each nozzle, and the storage tank 151 may supply an appropriate amount of substrate processing liquid to the inkjet head unit 140 based on the pressure provided by the pressure control module 152.

The substrate processing liquid providing unit 150 may be configured as an integrated module with the inkjet head unit 140. For example, the inkjet head unit 140 and the substrate processing liquid providing unit 150 may be disposed on the front surface of the gantry unit 130, and the substrate processing liquid providing unit 150 may be disposed at a higher level than the head base 220 including a plurality of head packs 210a, 210b, 210c, . . . , 210n. However, this embodiment is not limited to this. The substrate processing liquid providing unit 150 and the inkjet head unit 140 may be configured as separate modules. For example, the inkjet head unit 140 and the substrate processing liquid providing unit 150 may be arranged separately at the front and rear surfaces of the gantry unit 130.

The substrate processing apparatus 100 may be provided as a piezo-electric based inkjet printing system. In this case, the substrate processing apparatus 100 may fly the substrate processing liquid on the substrate G in the form of droplets through the nozzle of the inkjet head unit 140 according to the voltage applied to the piezo-electric element.

The substrate processing apparatus 100 can also be provided as an EHD (Electro Hydro Dynamic)-based inkjet printing system. In this case, electrostatic force acts on the substrate processing liquid when it is exposed to a strong local electric field, causing charging, and the substrate processing apparatus 100 may discharge the substrate processing liquid onto the substrate G according to the electrostatic mutual attraction caused by the charge injected into the substrate processing liquid. That is, the substrate processing apparatus 100 provides the substrate processing liquid in the form of a Taylor Cone according to the voltage (e.g., Pulse DC Voltage) difference between the inkjet head unit 140 and the substrate G, and the substrate processing liquid may be discharged onto the substrate G while forming a printed line from the nozzle to the substrate G.

When the substrate processing apparatus 100 is provided as a piezo-based inkjet printing system, the inkjet head unit 140 may be configured to include a piezoelectric element, a nozzle plate, a plurality of nozzles, etc. The nozzle plate constitutes the body of the inkjet head unit 140. A plurality of nozzles may be provided in multiple rows and multiple columns at regular intervals at the bottom of the nozzle plate, and the number of piezoelectric elements corresponding to the number of nozzles 220 may be provided in the nozzle plate. When configured in this way, the inkjet head unit 140 can discharge the substrate processing liquid onto the substrate G through the nozzle according to the operation of the piezoelectric element.

Meanwhile, the inkjet head unit 140 is also capable of independently adjusting the discharge amount of the substrate processing liquid provided through each nozzle according to the voltage applied to the piezoelectric element.

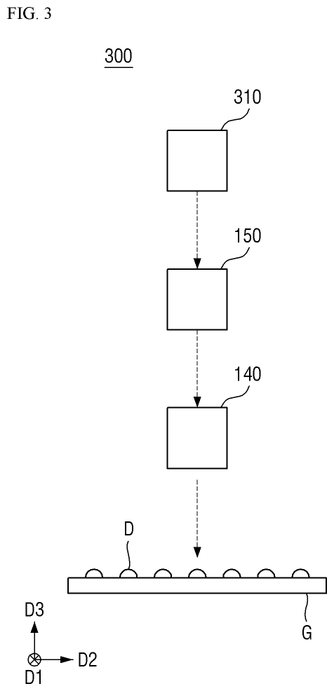

FIG. 3 is a block diagram schematically showing the internal configuration of a substrate processing system including a substrate processing apparatus. The substrate processing system 300 may include a substrate processing apparatus 100 and a substrate processing liquid storage device 310. In FIG. 3, the inkjet head unit 140 and the substrate processing liquid providing unit 150 are shown as being included in the substrate processing system 300, but this is only an example, and the substrate processing system 300 may include the entire substrate processing apparatus 100 including the inkjet head unit 140 and the substrate processing liquid providing unit 150. Hereinafter, the description of overlapping parts compared to the case of FIGS. 1 and 2 will be omitted, and only the parts corresponding to differences will be described.

The substrate processing liquid storage device 310 serves to periodically supply substrate processing liquid to the substrate processing liquid providing unit 150. The substrate processing liquid storage device 310 may be installed outside the substrate processing apparatus 100 and may be connected to the substrate processing liquid providing unit 150 disposed within the substrate processing apparatus 100 through a pipe or the like. The substrate processing liquid providing unit 150 transfers the substrate processing liquid provided by the substrate processing liquid storage device 310 to the inkjet head unit 140, and the inkjet head unit 140 may discharge the substrate processing liquid on the substrate G.

As described above, the substrate processing apparatus 100 may synchronize the position of the substrate G and the impact position of each nozzle within the inkjet head unit 140 in real time in order to discharge the substrate processing liquid at a desired position on the substrate G. Below, this is explained in detail.

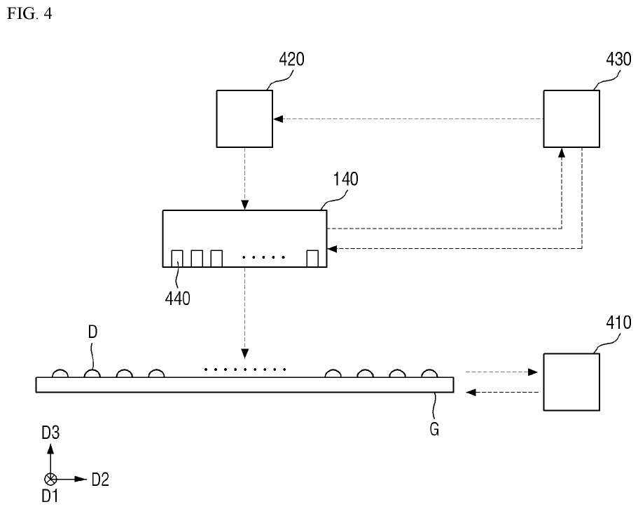

FIG. 4 is a first example diagram for explaining a first control unit, a second control unit, and a jetting driver that constitute a substrate processing apparatus. Referring to FIG. 4, the substrate processing apparatus 100 may be configured to include a first control unit 410, a jetting driver 420, and a second control unit 430.

The first control unit 410 may recognize the position of the substrate G. The first control unit 410 can recognize the position of the substrate G in real time. Additionally, the first control unit 410 can control the position and posture of the substrate G. The first control unit 410 may control the process processing unit 110 for this purpose.

The vision module 123 may obtain an image of the upper surface of the first stage 111 on which the substrate G is disposed. The first control unit 410 may recognize the position of the substrate G on the first stage 111 based on the image obtained by the vision module 123.

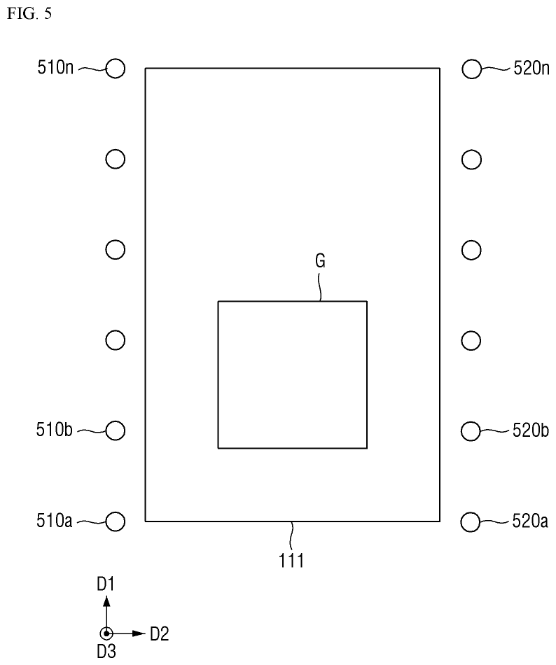

Referring to the example of FIG. 5, a plurality of sensors may be installed on both sides of the first stage 111. Hereinafter, the sensor installed on one side of the first stage 111 is defined as the first sensor 510a, 510b, . . . , 510n, and the sensor installed on the other side of the first stage 111 is defined as the second sensor 520a, 520b, . . . , 520n. FIG. 5 is a first example diagram for explaining the function of the first control unit constituting the substrate processing apparatus.

The plurality of first sensors 510a, 510b, . . . , 510n and the plurality of second sensors 520a, 520b, . . . , 520n may sense the substrate G disposed on the first stage 111. The first control unit 410 may recognize the position of the substrate G on the first stage 111 based on information obtained by the plurality of first sensors 510a, 510b, . . . , 510n and the plurality of second sensors 520a, 520b, . . . , 520n.

The plurality of first sensors 510a, 510b, . . . , 510n and the plurality of second sensors 520a, 520b, . . . , 520n may be arranged on the same line in the width direction (second direction D2) of the first stage 111. For example, the plurality of first sensors 510a, 510b, . . . , 510n may be provided as light-emitting devices, and the plurality of second sensors 520a, 520b, . . . , 520n may be provided as light-receiving devices. Alternatively, the plurality of first sensors 510a, 510b, . . . , 510n may be provided as light-receiving devices, and the plurality of second sensors 520a, 520b, . . . , 520n may be provided as light-emitting devices.

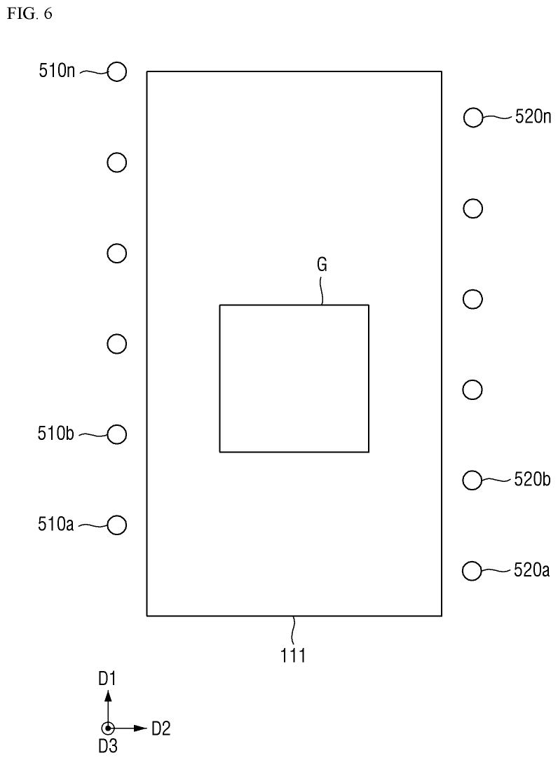

However, it is not limited to this, and it is also possible that the plurality of first sensors 510a, 510b, . . . , 510n and the plurality of second sensors 520a, 520b, . . . , 520n are not arranged on the same line in the width direction (second direction D2) of the first stage 111. For example, the plurality of first sensors 510a, 510b, . . . , 510n and the plurality of second sensors 520a, 520b, . . . , 520n may be arranged in a zigzag shape in the longitudinal direction (first direction D1) of the first stage 111 as shown in FIG. 6. FIG. 6 is a second example diagram for explaining the function of the first control unit constituting the substrate processing apparatus.

A plurality of first sensors 510a, 510b, . . . , 510n and a plurality of second sensors 520a, 520b, . . . , 520n may be provided in the same number on both sides of the first stage 111. However, it is not limited to this, and a plurality of first sensors 510a, 510b, . . . , 510n and a plurality of second sensors 520a, 520b, . . . , 520n may be provided in different numbers on both sides of the first stage 111. In this case, the plurality of first sensors 510a, 510b, . . . , 510n may be provided in greater numbers than the plurality of second sensors 520a, 520b, . . . , 520n. Alternatively, the plurality of first sensors 510a, 510b, . . . , 510n may be provided in fewer numbers than the plurality of second sensors 520a, 520b, . . . , 520n.

For example, when the plurality of first sensors 510a, 510b, . . . , 510n are provided in fewer numbers than the plurality of second sensors 520a, 520b, . . . , 520n, all of the plurality of first sensors 510a, 510b, . . . , 510n may be arranged on the same line as some of the second sensors 520a, 520b, . . . , 520n among the plurality of second sensors 520a, 520b, . . . , 520n. Alternatively, none of the plurality of first sensors 510a, 510b, . . . , 510n may be arranged on the same line as all of the plurality of second sensors 520a, 520b, . . . , 520n. Alternatively, some first sensors among the plurality of first sensors 510a, 510b, . . . , 510n may be arranged on the same line as some second sensors among the plurality of second sensors 520a, 520b, . . . , 520n, and some other first sensors may not be arranged on the same line as all of the plurality of second sensors 520a, 520b, . . . , 520n.

When the plurality of second sensors 520a, 520b, . . . , 520n are provided in fewer numbers than the plurality of first sensors 510a, 510b, . . . , 510n, the plurality of second sensors 520a, 520b, . . . , 520n may be arranged in the same or similar manner as the plurality of first sensors 510a, 510b, . . . , 510n.

Meanwhile, a plurality of sensors may be installed only on one side of the first stage 111, and the first control unit 410 may also use a plurality of sensors installed on one side of the first stage 111 to recognize the position of the substrate G on the first stage 111.

The first control unit 410 may know information about the size of the substrate G in advance. The first control unit 410 may also calculate information about the size of the substrate G based on the image of the entire substrate G obtained by the vision module 123.

The first control unit 410 may calculate information about the vertices of the substrate G based on the image of the entire substrate G obtained by the vision module 123. The first control unit 410 may calculate information about the vertex of the substrate G based on the sensing results of the plurality of first sensors 510a, 510b, . . . , 510n and the plurality of second sensors 520a, 520b, . . . , 520n. The first control unit 410 may calculate the position of a point on the substrate G where a droplet by a specific nozzle will be discharged based on information about the size of the substrate G and information about the vertices of the substrate G.

Meanwhile, the first control unit 410 may know the position of the discharge point within the substrate G in advance. In this case, the first control unit 410 may recognize the position of the substrate G and calculate the position of the discharge point within the substrate G from this.

Meanwhile, the first control unit 410 may estimate the position of the substrate G based on the control signal for the process processing unit 110. For example, the first control unit 410 may be provided including a motion controller that receives a motion signal from the process processing unit 110.

This will be described again with reference to FIG. 4.

The jetting driver 420 serves to control the nozzle 440 installed in the inkjet head unit 140. The nozzle 440 may discharge the substrate processing liquid onto the substrate G according to a signal input from the jetting driver 420.

The jetting driver 420 may be installed within the inkjet head unit 140. For example, the jetting driver 420 may be installed within the head frame 230. The jetting driver 420 can control the storage tank 151 and the pressure control module 152. The storage tank 151 may provide substrate processing liquid to each nozzle 440 installed in the head packs 210a, 210b, 210c, . . . , 210n under the control of the jetting driver 420. The pressure control module 152 can adjust the discharge timing of each nozzle 440 according to the control of the jetting driver 420. The jetting driver 420 controls the storage tank 151 and the pressure control module 152 to cause the nozzle 440 to discharge the substrate processing liquid onto the substrate G.

The second control unit 430 may recognize the position of the inkjet head unit 140. The second control unit 430 may recognize the position of the inkjet head unit 140 in real time. Additionally, the second control unit 430 may control the position and posture of the inkjet head unit 140. The second control unit 430 may control the gantry unit 130 and the inkjet head unit 140 for this purpose.

The second control unit 430 may control the jetting driver 420 based on information about the position of the inkjet head unit 140. The jetting driver 420 may control the nozzle 440 installed in the inkjet head unit 140 according to the control of the second control unit 430. For example, the second control unit 430 may be provided to include a laser control module (LCM) device for controlling the jetting driver 420.

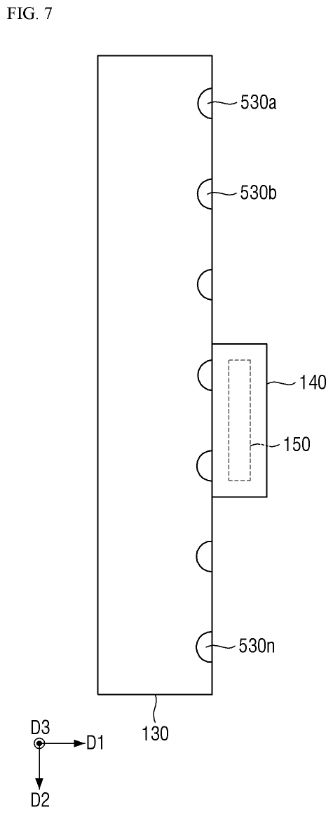

The second control unit 430 may recognize the position of the inkjet head unit 140 by using a plurality of sensors installed in the gantry unit 130. Hereinafter, the sensors installed in the gantry unit 130 are defined as third sensors 530a, 530b, . . . , 530n. FIG. 7 is a first example diagram for explaining the function of the second control unit constituting the substrate processing apparatus.

The plurality of third sensors 530a, 530b, . . . , 530n may be formed to be buried in the side surface of the gantry unit 130. A plurality of third sensors 530a, 530b, . . . , 530n may be formed on the side surface of the gantry unit 130 adjacent to the inkjet head unit 140.

The plurality of third sensors 530a, 530b, . . . , 530n may sense the position of the inkjet head unit 140 on the side surface of the gantry unit 130. The second control unit 430 may sense the position of the inkjet head unit 140 on the side surface of the gantry unit 130 based on the information obtained by the plurality of third sensors 530a, 530b, . . . , 530n.

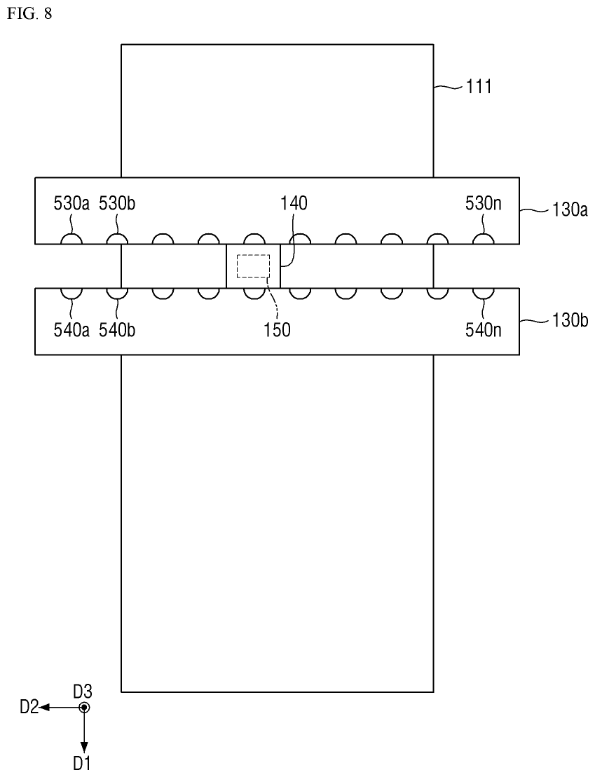

The load of the inkjet head unit 140 may be very large. Therefore, two gantry units may support the inkjet head unit 140. Hereinafter, the two gantry units disposed on both sides of the inkjet head unit 140 are defined as a first gantry module 130a and a second gantry module 130b, respectively. In addition, the sensor installed in the first gantry module 130a is defined as the third sensor 530a, 530b, . . . , 530n, and the sensor installed in the second gantry module 130b is defined as the fourth sensor 540a, 540b, . . . , 540n. FIG. 8 is a second example diagram for explaining the function of the second control unit constituting the substrate processing apparatus.

A plurality of third sensors 530a, 530b, . . . , 530n and a plurality of fourth sensors 540a, 540b, . . . , 540n may sense the inkjet head unit 140 on the side surfaces of the first gantry module 130a and the second gantry module 130b. The second control unit 430 may recognize the position of the inkjet head unit 140 on the side surfaces of the first gantry module 130a and the second gantry module 130b based on information obtained by the plurality of third sensors 530a, 530b, . . . , 530n and the plurality of fourth sensors 540a, 540b, . . . , 540n.

The plurality of third sensors 530a, 530b, . . . , 530n and the plurality of fourth sensors 540a, 540b, . . . , 540n may be arranged on the same line in the width direction (second direction D2) of the first stage 111. For example, the plurality of third sensors 530a, 530b, . . . , 530n may be provided as light-emitting devices, and the plurality of fourth sensors 540a, 540b, . . . , 540n may be provided as light-receiving devices. Alternatively, the plurality of third sensors 530a, 530b, . . . , 530n may be provided as light-receiving devices, and the plurality of fourth sensors 540a, 540b, . . . , 540n may be provided as light-emitting devices.

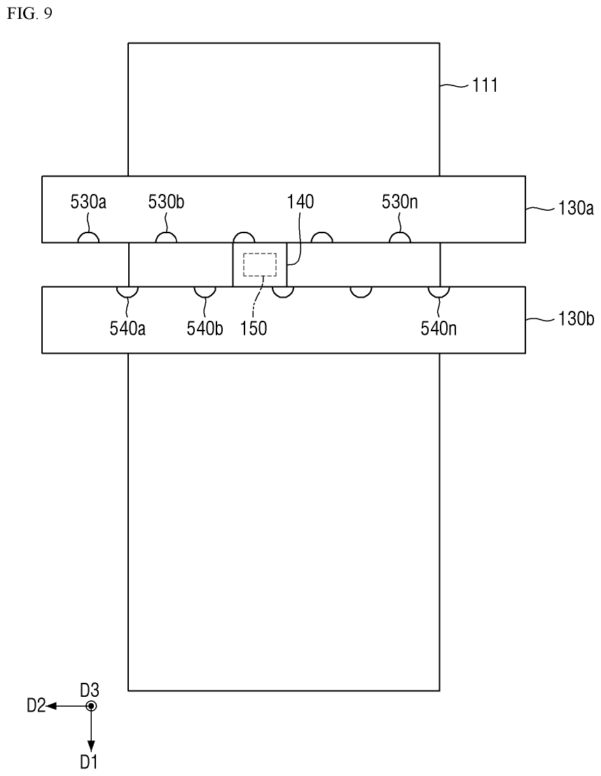

However, it is not limited to this, and it is also possible that the plurality of third sensors 530a, 530b, . . . , 530n and the plurality of fourth sensors 540a, 540b, . . . , 540n are not arranged on the same line in the width direction (second direction D2) of the first stage 111. For example, the plurality of third sensors 530a, 530b, . . . , 530n and the plurality of fourth sensors 540a, 540b, . . . , 540n may be arranged in a zigzag shape in the width direction (second direction D2) of the first stage 111 as shown in FIG. 9. FIG. 9 is a third example diagram for explaining the function of the second control unit constituting the substrate processing apparatus.

A plurality of third sensors 530a, 530b, . . . , 530n and a plurality of fourth sensors 540a, 540b, . . . , 540n may be provided in the same number in the first gantry module 130a and the second gantry module 130b, respectively. However, it is not limited to this, and the plurality of third sensors 530a, 530b, . . . , 530n and the plurality of fourth sensors 540a, 540b, . . . , 540n may be provided in different numbers in the first gantry module 130a and the second gantry module 130b, respectively. In this case, the plurality of third sensors 530a, 530b, . . . , 530n may be provided in greater numbers than the plurality of fourth sensors 540a, 540b, . . . , 540n. Alternatively, the plurality of third sensors 530a, 530b, . . . , 530n may be provided in fewer numbers than the plurality of fourth sensors 540a, 540b, . . . , 540n.

For example, when the plurality of third sensors 530a, 530b, . . . , 530n are provided in fewer numbers than the plurality of fourth sensors 540a, 540b, . . . , 540n, all of the plurality of third sensors 530a, 530b, . . . , 530n may be arranged on the same line as some of the second sensors among the plurality of fourth sensors 540a, 540b, . . . , 540n. Alternatively, none of the plurality of third sensors 530a, 530b, . . . , 530n may be arranged on the same line as all of the plurality of fourth sensors 540a, 540b, . . . , 540n. Alternatively, some first sensors among the plurality of third sensors 530a, 530b, . . . , 530n may be arranged on the same line as some second sensors among the plurality of fourth sensors 540a, 540b, . . . , 540n, and some other first sensors may not be arranged on the same line as all of the plurality of fourth sensors 540a, 540b, . . . , 540n.

When the plurality of fourth sensors 540a, 540b, . . . , 540n are provided in fewer numbers than the plurality of third sensors 530a, 530b, . . . , 530n, the plurality of fourth sensors 540a, 540b, . . . , 540n may be arranged in the same or similar manner as the plurality of third sensors 530a, 530b, . . . , 530n.

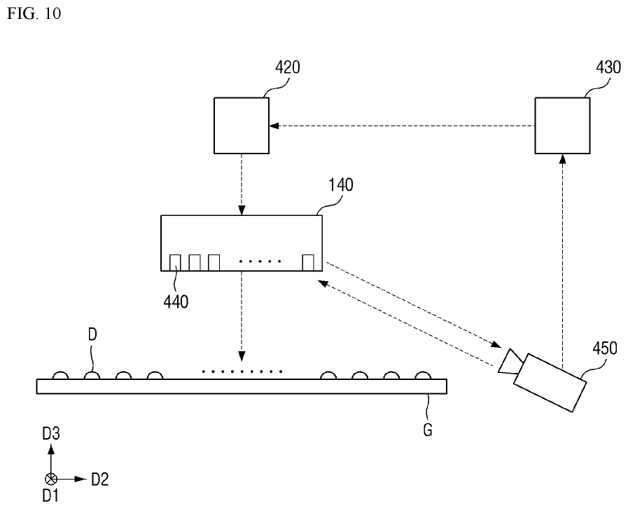

The second control unit 430 may recognize the position of the inkjet head unit 140 using the camera sensor 450. The substrate processing apparatus 100 may further include a camera sensor 450. FIG. 10 is a fourth example diagram for explaining the function of the second control unit constituting the substrate processing apparatus.

The camera sensor 450 may be installed at a level lower than the inkjet head unit 140. The camera sensor 450 may be installed at the same level as the substrate G.

Alternatively, the camera sensor 450 may be installed at a level higher than the substrate G and lower than the inkjet head unit 140.

The camera sensor 450 may obtain images including the gantry units 130, 130a, and 130b and the inkjet head unit 140. The second control unit 430 may recognize the position of the inkjet head unit 140 on the side surface of the gantry units 130, 130a, and 130b based on the image obtained by the camera sensor 450.

The second control unit 430 may know information about the size of the inkjet head unit 140 in advance. The second control unit 430 may also calculate information about the size of the inkjet head unit 140 based on the image of the entire inkjet head unit 140 obtained by the camera sensor 450.

The second control unit 430 may calculate information about the vertices of the inkjet head unit 140 based on the image of the entire inkjet head unit 140 obtained by the camera sensor 450. The second control unit 430 may calculate information about vertices of the inkjet head unit 140 based on the sensing results of the plurality of third sensors 530a, 530b, . . . , 530n and the plurality of fourth sensors 540a, 540b, . . . , 540n. The second control unit 430 may calculate the position of a specific nozzle selected from a plurality of nozzles based on information about the size of the inkjet head unit 140 and information about the vertex of the inkjet head unit 140.

The camera sensor 450 may obtain images of a plurality of nozzles exposed to the bottom surface of the inkjet head unit 140. The second control unit 430 may calculate the position for a specific nozzle selected from among a plurality of nozzles based on images including the gantry units 130, 130a, 130b and the inkjet head unit 140 and images of a plurality of nozzles exposed to the bottom surface of the inkjet head unit 140.

Meanwhile, the second control unit 430 may know the position of each nozzle within the inkjet head unit 140 in advance. In this case, the second control unit 430 may recognize the position of the inkjet head unit 140 and calculate the position of each nozzle within the inkjet head unit 140 from this.

Meanwhile, the second control unit 430 may also perform maintenance on the inkjet head unit 140. The second control unit 430 may correct the substrate processing liquid discharge position of each nozzle provided in the inkjet head unit 140 based on the droplet (D) measurement result of the droplet inspection unit. The second control unit 430 may detect a defective nozzle (for example, a nozzle that does not discharge substrate processing liquid) among a plurality of nozzles and perform a cleaning operation on the defective nozzle.

The first control unit 410 and the second control unit 430 may include one or more modules related to functions or operations for controlling the substrate processing apparatus 100 and/or the substrate processing liquid storage device 310. The module may be provided in the form of an application or program, and may be implemented as instructions stored in a computer-readable recording medium (e.g., hard disk, portable disk such as CD-ROM or DVD, semiconductor memory such as flash memory, etc.). When the instruction is executed by a processor, the processor can perform the function corresponding to the instruction. Instructions may include code generated by a compiler or code that can be executed by an interpreter. The first control unit 410 and the second control unit 430 can be provided as a computing device that communicates with the substrate processing apparatus 100 and/or the substrate processing liquid storage device 310 through a wired or wireless network for information processing, data provision, etc.

In the above description, the first control unit 410 and the second control unit 430 may be included in the substrate processing apparatus 100. However, it is not limited to this, and the first control unit 410 and the second control unit 430 may be provided separately from the substrate processing apparatus 100. For example, the first control unit 410 and the second control unit 430 may not be included in the substrate processing apparatus 100 but may be included in the substrate processing system 300.

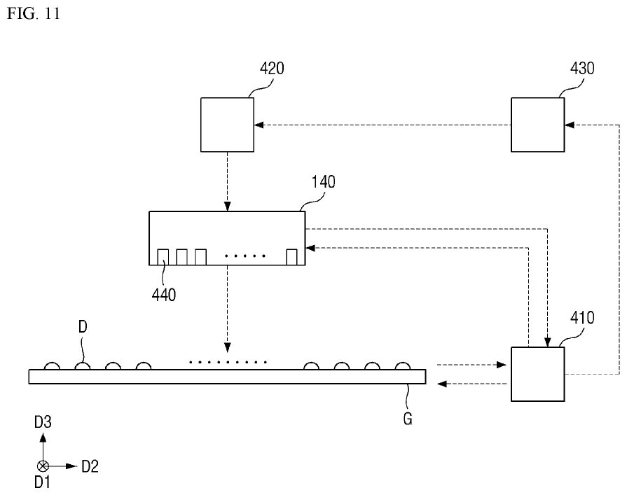

In the above description, the second control unit 430 recognizes the position of the inkjet head unit 140 and controls the position and posture of the inkjet head unit 140. However, it is not limited to this, and it is also possible for the first control unit 410 to recognize the position of the inkjet head unit 140 and control the position and posture of the inkjet head unit 140. In this case, the second control unit 430 may determine the position of the inkjet head unit 140 based on the information provided by the first control unit 410. FIG. 11 is a second example diagram for explaining a first control unit, a second control unit, and a jetting driver that constitute a substrate processing apparatus.

The first control unit 410 may recognize the position of the inkjet head unit 140 using a plurality of third sensors 530a, 530b, . . . , 530n installed in the gantry unit 130. The first control unit 410 may recognize the position of the inkjet head unit 140 using a plurality of third sensors 530a, 530b, . . . , 530n and a plurality of fourth sensors 540a, 540b, . . . , 540n respectively installed in the first gantry module 130a and the second gantry module 130b. The first control unit 410 may recognize the position of the inkjet head unit 140 using the camera sensor 450. When the first control unit 410 recognizes the position of the inkjet head unit 140, the methods described above can be applied.

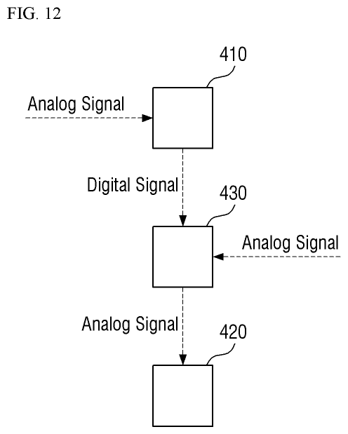

FIG. 12 is an example diagram for explaining signals input and output from the first control unit and the second control unit constituting the substrate processing apparatus. The following description refers to FIG. 12.

The first control unit 410 may recognize the position of the substrate G. The first control unit 410 may recognize the position of each point on the substrate G where the droplet D will be discharged. The first control unit 410 may use the vision module 123 to recognize the position of the substrate G or the position of each point on the substrate G where the droplet D will be discharged. The first control unit 410 may recognize the position of the substrate G or the position of each point where the droplet D will be discharged on the substrate G by using a plurality of first sensors 510a, 510b, . . . , 510n and a plurality of second sensors 520a, 520b, . . . , 520n installed on both sides of the first stage 111. The first control unit 410 may use a plurality of sensors installed on one side of the first stage 111 to recognize the position of the substrate G or the position of each point where the droplet D will be discharged on the substrate G. The plurality of sensors installed on one side of the first stage 111 may be a plurality of first sensors 510a, 510b, . . . , 510n or a plurality of second sensors 520a, 520b, . . . , 520n.

The second control unit 430 may recognize the position of the inkjet head unit 140.

The second control unit 430 may recognize the position of each nozzle installed in the inkjet head unit 140. The second control unit 430 may recognize the position of the inkjet head unit 140 or the position of each nozzle installed in the inkjet head unit 140 using the camera sensor 450. The second control unit 430 may recognize the position of the inkjet head unit 140 or the position of each nozzle installed in the inkjet head unit 140 using a plurality of third sensors 530a, 530b, . . . , 530n installed in the gantry unit 130. The second control unit 430 may recognize the position of the inkjet head unit 140 or the position of each nozzle installed in the inkjet head unit 140 using a plurality of third sensors 530a, 530b, . . . , 530n and a plurality of fourth sensors 540a, 540b, . . . , 540n respectively installed in the first gantry module 130a and the second gantry module 130b. The position of the inkjet head unit 140 or the position of each nozzle installed in the inkjet head unit 140 may be recognized by the first control unit 410.

The signal input to the first control unit 410 may be an analog communication signal (Analog Signal). Signals input to the first control unit 410 include the photographing result of the vision module 123, the sensing result of the plurality of first sensors 510a, 510b, . . . , 510n, and the sensing result of the plurality of second sensors 520a, 520b, . . . , 520n, etc.

The signal input to the second control unit 430 may be an analog communication signal. Signals input to the first control unit 430 include the photographing result of the camera sensor 450, the sensing result of the plurality of third sensors 530a, 530b, . . . , 530n, and the sensing result of the plurality of fourth sensors 540a, 540b, . . . , 540n, etc.

The signal output from the second control unit 430 may be an analog communication signal. The signal output from the second control unit 430 may be a signal for controlling the jetting driver 420.

The signal transmitted from the first control unit 410 to the second control unit 430 may be a digital communication signal. For example, EtherCAT (Ethernet for Control Automation Technology) communication may be performed between the first control unit 410 and the second control unit 430.

The first control unit 410 and the second control unit 430 can synchronize signals using EtherCAT communication. In the present disclosure, the position of the substrate G and the impact position of each nozzle in the inkjet head unit 140 can be synchronized in real time based on signal synchronization between the first control unit 410 and the second control unit 430. Accordingly, the substrate processing liquid can be appropriately discharged at a desired position on the substrate G.

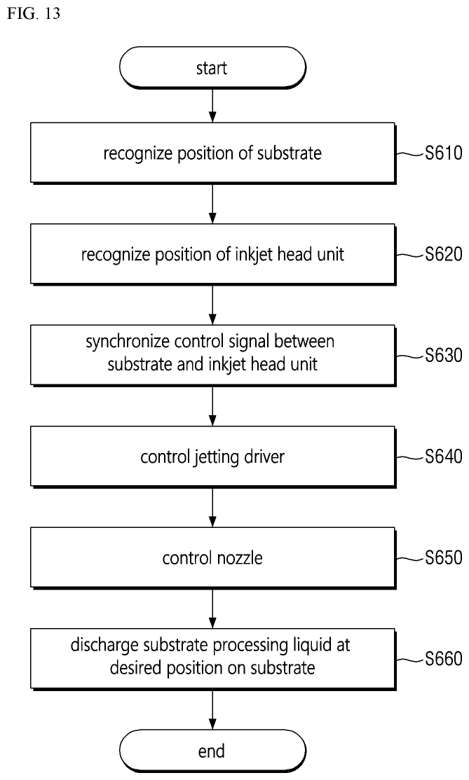

Next, the substrate processing method of the substrate processing apparatus 100 will be described. FIG. 13 is a flowchart sequentially explaining the substrate processing method of the substrate processing apparatus.

First, the first control unit 410 recognizes the position of the substrate G (S610). The first control unit 410 may recognize the position of the substrate G using the vision module 123. Alternatively, the first control unit 410 may recognize the position of the substrate G using a plurality of first sensors 510a, 510b, . . . , 510n and/or a plurality of second sensors 520a, 520b, . . . , 520n. The first control unit 410 may recognize the position of each point on the substrate G where the droplet D will be discharged.

Afterwards, the second control unit 430 recognizes the position of the inkjet head unit 140 (S620). The second control unit 430 may recognize the position of the inkjet head unit 140 using the camera sensor 450. Alternatively, the second control unit 430 may recognize the position of the inkjet head unit 140 using a plurality of third sensors 530a, 530b, . . . , 530n. Alternatively, the second control unit 430 may recognize the position of the inkjet head unit 140 using a plurality of third sensors 530a, 530b, . . . , 530n and a plurality of fourth sensors 540a, 540b, . . . , 540n. The second control unit 430 may recognize the position of each nozzle within the inkjet head unit 140.

Recognition of the position of the substrate G and recognition of the position of the inkjet head unit 140 may be performed sequentially. As described above, the position of the substrate G may be recognized first, and then the position of the inkjet head unit 140 may be recognized. However, it is not limited to this, and it is possible to recognize the position of the substrate G and the position of the inkjet head unit 140 at the same time. Alternatively, it is possible to recognize the position of the inkjet head unit 140 first, and then to recognize the position of the substrate G.

Meanwhile, in this embodiment, it is possible for the first control unit 410 to both recognize the position of the substrate G and the position of the inkjet head unit 140.

After recognizing the position of the substrate G (S610) and recognizing the position of the inkjet head unit 140 (S620), the first control unit 410 and the second control unit 430 synchronize a control signal using EtherCAT communication (S630). The first control unit 410 and the second control unit 430 can also synchronize a control signal using wired or wireless communication other than EtherCAT communication.

The first control unit 410 can control the position of the substrate G, and the second control unit 430 can control the position of the inkjet head unit 140. According to the synchronization of the control signal, the position of each point on the substrate G where the droplet D will be discharged and the impact position of each nozzle within the inkjet head unit 140 can be synchronized in real time.

Thereafter, the second control unit 430 controls the jetting driver 420 based on the position recognition result of the substrate G and the position recognition result of the inkjet head unit 140 (S640). The jetting driver 420 can control each nozzle in the inkjet head unit 140 according to the control of the second control unit 430 (S650), and the nozzle can discharge the substate processing liquid on the substrate G according to the signal input from the jetting driver 420 (S660). According to this embodiment, it becomes possible to appropriately discharge the substrate processing liquid to a desired position on the substrate G according to synchronization of the control signal.

The present disclosure relates to an encoder system for improving the accuracy of impact point of a substrate processing liquid on a substrate G. In the present disclosure, the same encoder signal can be shared between the motion controller and the jetting driver, thereby minimizing the temporal period deviation of the encoder signal applied to each jetting driver and improving signal stability.

In the present disclosure, jetting signal control is possible with a single encoder for motion control by using an LCM device that is synchronized with a motion controller. In other words, it is possible to control motion and inkjet jetting signals with a single encoder. Additionally, in the present disclosure, control can be performed using a combination of analog communication signals and digital communication signals. In other words, control can be performed not only with analog signals, but with a combination of analog communication signals and digital communication signals.

According to the present disclosure, analog signal attenuation is eliminated and signal delay due to distance and signal multiplier is eliminated. Additionally, as the size and volume of the substrate processing apparatus 100 increases, signal restrictions due to long-distance signal transmission are eliminated even if long-distance signal transmission occurs. Additionally, signal synchronization is possible based on the motion encoder signal, and time synchronization between the motion controller and jetting driver can also be improved.

Although the embodiments of the present disclosure have been described with reference to the above and accompanying drawings, those skilled in the art to which the present disclosure pertains can understand that the present disclosure can be practiced in other specific forms without changing the technical concept or features. Therefore, the embodiments described above should be understood as illustrative in all respects and not limiting.

What is claimed is:

1. An apparatus for processing a substrate comprising:
a process processing unit including a stage supporting a substrate and configured to move the substrate on the stage;
an inkjet head unit configured to discharge a substrate processing liquid onto the substrate;
a gantry unit configured to move the inkjet head unit; and
a jetting driver configured to control discharge of the substrate processing liquid,
wherein a first signal controlling a position of the substrate and a second signal controlling a position of the inkjet head unit are synchronized.

2. The apparatus of claim 1 further comprises,
a first control unit configured to recognize and control a position of the substrate; and
a second control unit configured to control the jetting driver.

3. The apparatus of claim 2, wherein the first control unit or the second control unit recognizes and controls a position of the inkjet head unit.

4. The apparatus of claim 2, wherein a transmission signal between the first control unit and the second control unit is a digital signal.

5. The apparatus of claim 2, wherein a transmission signal between the second control unit and the jetting driver is an analog signal.

6. The apparatus of claim 2, wherein the first control unit and the second control unit perform signal synchronization.

7. The apparatus of claim 1, wherein the jetting driver operates when signals are synchronized.

8. The apparatus of claim 1, wherein a position of each discharge point on the substrate and a position of each nozzle within the inkjet head unit are synchronized in real time.

9. The apparatus of claim 1, wherein a third signal controlling the jetting driver is synchronized with the first signal and/or the second signal.

10. The apparatus of claim 1, wherein the first control unit recognizes a position of the substrate using a first camera sensor or a plurality of sensors disposed on one or both sides of the stage.

11. The apparatus of claim 10, wherein the first camera sensor is disposed above the substrate.

12. The apparatus of claim 1, wherein the first control unit calculates a position of each discharge point on the substrate based on information about a size of the substrate and information about a vertex of the substrate.

13. The apparatus of claim 1, wherein the second control unit recognizes a position of the inkjet head unit using a second camera sensor or a plurality of sensors disposed on a side surface of the gantry unit.

14. The apparatus of claim 13, wherein the second camera sensor is disposed lower than the inkjet head unit.

15. The apparatus of claim 1, wherein the second control unit calculates a position of each nozzle in the inkjet head unit based on information about a size of the inkjet head unit and information about a vertex of the inkjet head unit.

16. A method for processing a substrate comprising:
recognizing a position of a substrate;
recognizing a position of an inkjet head unit for discharging a substrate processing liquid on the substrate;
synchronizing a first signal controlling a position of the substrate and a second signal controlling a position of the inkjet head unit; and
controlling discharge of the substrate processing liquid based on synchronization of the first signal and the second signal.

17. The method of claim 16, wherein position control of the substrate and position control of the inkjet head unit are related to a first control unit, and discharge of the substrate processing liquid is related to a second control unit.

18. The method of claim 17, wherein a transmission signal between the first control unit and the second control unit is a digital signal.

19. The method of claim 16, wherein position control of the substrate is related to a first control unit, and position control of the inkjet head unit is related to a second control unit.

20. An apparatus for processing a substrate comprising:
a process processing unit including a stage supporting a substrate and configured to move the substrate on the stage;
an inkjet head unit configured to discharge a substrate processing liquid onto the substrate;
a gantry unit configured to move the inkjet head unit;
a jetting driver configured to control discharge of the substrate processing liquid;
a first control unit configured to recognize and control a position of the substrate; and
a second control unit configured to control the jetting driver,
wherein a first signal controlling a position of the substrate and a second signal controlling a position of the inkjet head unit are synchronized,
wherein the first control unit or the second control unit recognizes and controls a position of the inkjet head unit,
wherein a transmission signal between the first control unit and the second control unit is a digital signal,
wherein a transmission signal between the second control unit and the jetting driver is an analog signal.
